(19) United States
(12) Patent Application Publication
(10) Pub. No.: US 2015/0309306 A1
(43) Pub. Date: Oct. 29, 2015

(54) APPLICATIONS OF CONTACT-TRANSFER PRINTED MEMBRANES

(71) Applicant: MASSACHUSETTS INSTITUTE OF TECHNOLOGY, Cambridge, MA (US)

(72) Inventors: Apoorva MURARKA, Cambridge, MA (US); Vladimir BULOVIC, Lexington, MA (US); Annie I-Jen WANG, Cambridge, MA (US); Jeffrey Hastings LANG, Sudbury, MA (US)

(73) Assignee: MASSACHUSETTS INSTITUTE OF TECHNOLOGY, Cambridge, MA (US)

(21) Appl. No.: 14/281,588

(22) Filed: May 19, 2014

Related U.S. Application Data
(63) Continuation of application No. 13/844,270, filed on Mar. 15, 2013.
Application No. 13/844,270 is a continuation-in-part of application No. 13/604,613, filed on Sep. 5, 2012.
Application No. 13/604,613 is a continuation-in-part of application No. 12/636,757, filed on Dec. 13, 2009, now Pat. No. 8,739,390.
Application No. 12/636,757 is a continuation-in-part of application No. 12/903,149, filed on Oct. 12, 2010, now Pat. No. 8,963,262.
(60) Provisional application No. 61/696,041, filed on Aug. 31, 2012.
(60) Provisional application No. 61/528,148, filed on Aug. 27, 2011.
(60) Provisional application No. 61/138,014, filed on Dec. 16, 2008.
(60) Provisional application No. 61/251,255, filed on Oct. 13, 2009.

(51) Int. Cl. G02B 26/08; B81B 3/00

(52) U.S. Cl. CPC G02B 26/0841; G02B 26/0825; B81B 3/0021; B81B 2201/042

(57) ABSTRACT

The disclosed embodiments provide sensitive pixel arrays formed using solvent-assisted or unassisted release processes. Exemplary devices include detectors arrays, tunable optical instruments, deflectable minors, digital micro-mirrors, digital light processing chips, tunable optical micro-cavity resonators, acoustic sensors, acoustic actuators, acoustic transducer devices and capacitive zipper actuators to name a few.

The application claims the filing-date priority of application Ser. No. 13/844,270, filed Mar. 15, 2013, which claimed priority to Provisional Application Ser. No. 61/696,041, filed Aug. 31, 2012; application Ser. No. 13/604,613, filed Sep. 5, 2012 (which claims priority to Provisional Application No. 61/528,148, filed Aug. 27, 2011); and application Ser. No. 12/636,757, filed Dec. 13, 2009 (which claims priority to Provisional Application No. 61/138,014, filed Dec. 16, 2008); and application Ser. No. 12/903,149, filed Oct. 12, 2010 (which claims priority to Provisional Application No. 61/251,255, filed Oct. 13, 2009). The disclosure of each of these applications are incorporated herein in its entirety.

### BACKGROUND

1. Field of the Invention

The disclosure relates to method and apparatus for micro-contact printing of micro-electromechanical systems (“MEMS”). More specifically, the disclosure relates to novel applications and methods for release-assisted micro-contact printing of MEMS.

2. Description of Related Art

MEMS applied over large areas enable applications in such diverse areas as sensor skins for humans and vehicles, phased array detectors and adaptive-texture surfaces. MEMS can be incorporated into large area electronics. Conventional photolithography-based methods for fabricating MEMS have provided methods and tools for producing small features with extreme precision in processes that can be integrated with measurement and control circuits. However, the conventional methods are limited to working within the existing silicon semiconductor-based framework. Several challenges, including expense, limited size and form-factor, and a restricted materials set, prevent the future realization of new MEMS for applications beyond single chip or single sensor circuits. Standard processing techniques are particularly restrictive when considering expanding into large area fabrication. Conventional photolithography methods are also incompatible with printing flexible substrate MEMS and micro-sized sensor arrays.

For example, in creating free-standing bridges, cantilevers or membranes from limited material, the conventional methods require surface or bulk micromachining, a series of photolithographic masking steps, thin film depositions, and wet chemical or dry etch releases. Such steps require investing in and creating highly specialized mask sets which render conventional photolithography expensive and time and labor intensive. While the initial investment can be recovered by producing large batches of identical MEMS devices, the conventional methods are cost prohibitive for small batches or for rapid prototype production.

Conventional MEMS have been based on silicon, silicon dioxide, and silicon nitride which are deposited and patterned using known facile processes. Incorporating mechanical elements made of metal on this scale is difficult because of the residual stresses and patterning challenges of adding metal to the surface. This is because metals are resistant to aggressive plasma etching. As a result, conventional MEMS processing applies liftoff or wet chemical etching. The surface tension associated with drying solvent during these patterning steps or a later immersion can lead to stiction (or sticking) of the released structure. Stiction dramatically reduces the production yield.

Another consideration in some large area applications is flexibility. Although photolithography is suitable for defining high fidelity patterns on planar and rigid substrates, it is difficult to achieve uniform registration and exposure over large areas. Display technologies have been among the first applications to create a market for large area microelectronics. To meet the challenges of new markets for large area electronics, alternative means to patterning have been proposed which include: shadow masking, inkjet printing, and micro-contact printing. These techniques are often the only options available for organic semiconductors and other nanostructured optoelectronic materials, some of which have particularly narrow threshold for temperature, pressure and solvent. Conventional methods are not suitable for MEMS using organic semiconductors, nanostructured optoelectronic materials which may be fabricated on a flexible substrate.

An alternative approach is to fabricate electronic structures directly on flexible sheets but polymeric substrates offering this flexibility are typically limited to low-temperature processing as they degrade under high temperature processing. Accordingly, high temperature processing such as thermal growth of oxides and the deposition of polysilicon on a flexible substrate cannot be supported by conventional processes. Another approach is to fabricate structures on silicon wafers, bond them to a flexible sheet, and then release the structures from the silicon by fracturing small supports or by etching a sacrificial layer. However, this approach tends to locate the structures on the surface having the highest strain during bending.

Therefore, there is a need for improved processes that enable construction of novel MEMS devices heretofore unattainable.

### SUMMARY

In one embodiment, the disclosure relates to an array of addressable membranes, the array comprising a metallic membrane formed over a substrate, the substrate having a plurality of cavities; a first electrode integrated with the first of the plurality of cavities and forming a first electrode pair with a corresponding first portion of the membrane, the corresponding first portion of the membrane defining a first diaphragm; a power source for biasing the first electrode pair thereby deflecting the first diaphragm responsive to an applied bias. The bias may include a time-varying signal. The cavities may have different shapes, depths and/or sizes. The array may further comprise a meter in communication with a plurality of electrode pairs for detecting a capacitance change between the first electrode and the first diaphragm when an external signal impacts the membrane. The array may further comprise a controller in communication with the meter, the controller may have a processor circuit in communication with a memory circuit, the controller receives a signal from the meter and identifies a change in capacitance corresponding to the received signal. The electrode pair communicates a change in potential between the first electrode and the diaphragm when the diaphragm is deflected or a change in current when the diaphragm is deflecting. The substrate may be rigid or flexible. An exemplary substrate is ITO-PET. The metallic membrane can be one or more of gold, silver, aluminum, chrome, copper or combinations thereof.

In another embodiment, the disclosure relates to an array of addressable membranes, the array comprising: a plurality of membranes arranged over a substrate, a first of the plurality of membranes forming a first diaphragm over a first cavity formed in the substrate; a first electrode integrated with the first cavity and communicating with the first diaphragm, the first electrode and the first diaphragm forming a first electrode pair; and a power source for biasing the first electrode pair; wherein the diaphragm deflects responsive to an applied bias from the power source. The diaphragm may deflect responsive to an external mechanical, acoustic, pneumatic or gas pressure signal. The array may further comprise a meter in communication with the first electrode pair for detecting a capacitance change between the first electrode and the first diaphragm responsive to an external signal. The array may further comprise a controller in communication with the meter, the controller may have a processor circuit in communication with a memory circuit. The controller receives a signal from the meter and identifying a change in capacitance corresponding to the received signal. The first electrode pair communicates a change in potential between the first electrode and the diaphragm when the diaphragm is deflected or a when there is a change in current when the diaphragm is deflecting. At least one of the cavities can have one or more sidewalls. Each of the plurality of membranes can have a thickness gradient.

In another embodiment, the disclosure relates to a tunable optical device, comprising a substrate defining an array of cavities with each cavity supporting an electrode; a reflective membrane formed over the substrate so as to form a plurality of diaphragms, each diaphragm corresponding to a respective one of the plurality of cavities and each diaphragm and corresponding electrode defining an electrode pair; power source for biasing a first electrode pair and a second electrode pair; wherein each of the first electrode pair and the second electrode pair deflects responsive to an applied bias thereby distorting reflection of an incident light. The first electrode pair and the second electrode pair can deflect in substantially the same direction or in different directions. The power source may bias the first electrode pair independently of the second electrode pair. The power source may also bias the first electrode and the second electrode pairs substantially simultaneously or sequentially.

In another embodiment, the disclosure relates to an tunable optical micromirror device, comprising: a diaphragm formed over a cavity and supported by a structure; a first electrode and a second electrode positioned in the cavity; a power supply for biasing each of the first electrode, the second electrode and the diaphragm; and a controller for controlling the power supply to bias one or more of the first electrode, the second electrode and the diaphragm; wherein the controller activates the first electrode or the second electrode, and wherein activating one of the first electrode or the second electrode deflects a region of the diaphragm. The diaphragm (or membrane) can be a composite of metallic, semiconductor and non-conductive material. The first or the second electrode may be integrated into the cavity. In an embodiment, the controller activates the first electrode or the second electrode independently of each other. The electrodes can be positioned at or below the cavity or may be integrated with the cavity.

In still another embodiment, the disclosure relates to an array of addressable membranes, the array comprising: a metal membrane formed over a substrate, the substrate having a plurality of cavities and the membrane defining a plurality of diaphragms corresponding to each of the respective plurality of cavities; a first electrode integrated with the first of the plurality of cavities and forming a first electrode pair with a first diaphragm; a second electrode integrated with the second of the plurality of cavities and forming a second electrode pair with a second diaphragm; and a power source for biasing the first and the second electrode pairs to thereby deflect the first and the second diaphragms responsive to an applied bias; wherein the metal membrane has a thickness gradient. The array may further comprise a meter which communicates with the first electrode pair and detects a capacitance change between the first diaphragm and the first electrode responsive to an external signal impact on the diaphragm. The membrane may have a thickness gradient that is continuous or stepwise. Further, the gradient can change in one or both a Cartesian geometry or in a cylindrical/ polar geometry. The gradient may also change such that the membrane is thickest at one end and thinnest at another.

In yet another embodiment, the disclosure relates to an array of addressable pixels, the array comprising: a substrate defining a plurality of cavities thereon; a membrane covering a portion of the substrate and forming a plurality of diaphragms with the respective plurality of the cavities; a first electrode integrated with a first of the plurality of cavities and forming a first electrode pair with a corresponding first diaphragm; and a second electrode integrated with a second of the plurality of cavities and forming a second electrode pair with a corresponding second diaphragm; wherein the membrane is a composite of a first and a second material, and wherein the first material and the second material have a complementary thickness gradient such that as the thickness of the first and the second material varies across the substrate, the composite thickness remains substantially constant. Each electrode pair may define a pixel. The array may further comprise a power source for biasing the first and the second electrode pairs to thereby deflect the diaphragm responsive to an applied bias. The array may further comprise a controller interposed between the power source and the electrode pairs, the controller independently addressing the first and the second electrode pair. A detector may also be included for capacitively detecting deflection in a first of the plurality of diaphragms.

In another embodiment, the disclosure relates to an array of addressable membranes, the array comprising: a membrane formed over a substrate; a plurality of cavities formed in the substrate, a first of the plurality of cavities having one of a shape, size or depth different from a second of the plurality of cavities; a first electrode integrated with the first of the plurality of cavities and forming a first electrode pair with a corresponding first portion of the membrane; and a power source for biasing the first electrode pair thereby deflecting the first portion of the membrane responsive to an applied bias. The membrane may have one of a uniform or a non-uniform thickness.

The disclosed embodiments provide sensitive pixel arrays formed using solvent-assisted or unassisted release processes. Exemplary devices include detectors arrays, tunable optical instruments, deflectable minors, digital micro-mirrors, digital light processing chips, tunable optical micro-cavity resonators, acoustic devices and zipper actuators to name a few.

In one embodiment, the disclosure relates to an array of addressable membranes, the array having: a metallic membrane formed over a substrate, the substrate having a plurality of cavities; a first electrode integrated with the first of the plurality of cavities and forming a first electrode pair with a corresponding first portion of the membrane; a power source for biasing the first electrode pair thereby deflecting the first portion of the membrane responsive to an applied bias, signal and/or in response to an externally applied mechanical, acoustic or pneumatic pressure. The substrate can be flexible or rigid.

In another embodiment, the disclosure relates to an array of addressable membranes, the array comprising: a plurality of membranes arranged over a substrate, a first of the plurality of membranes forming a first diaphragm over a first cavity formed in the substrate; a first electrode integrated with the first cavity and communicating with the first diaphragm, the first electrode and the first diaphragm forming a first electrode pair; and a power source for biasing the first electrode pair; wherein the diaphragm deflects responsive to an applied bias, signal and/or in response to an externally applied mechanical, acoustic or pneumatic pressure.

In another embodiment, the disclosure relates to an optically tunable filter, comprising: a substrate defining an array of cavities with each cavity supporting an electrode; a reflective membrane formed over the substrate so as to form a plurality of diaphragms, each diaphragm corresponding to a respective one of the plurality of cavities and each diaphragm and corresponding electrode defining an electrode pair; power source for biasing a first electrode pair and a second electrode pair; wherein each of the first electrode pair and the second electrode pair deflects responsive to an applied bias thereby distorting reflection of an incident light.

In still another embodiment, the disclosure relates to an addressable optical filter, comprising: a diaphragm formed over a cavity and supported by a structure; a first electrode and a second electrode positioned at, in or below the cavity; a power supply for biasing each of the first electrode, the second electrode and the diaphragm; and a controller for controlling the power supply to bias one or more of the first electrode, the second electrode and the diaphragm; wherein the controller activates the first electrode or the second electrode, and wherein activating one of the first electrode or the second electrode deflects a region of the diaphragm.

In yet another embodiment, the disclosure relates to an array of addressable membranes, the array comprising: a metal membrane formed over a substrate, the substrate having a plurality of cavities, a first electrode integrated with the first of the plurality of cavities and forming a first electrode pair with a corresponding first portion of the membrane; a second electrode integrated with the second of the plurality of cavities and forming a second electrode pair with a corresponding second portion of the membrane; and a power source for biasing the first and the second electrode pairs to thereby deflect the diaphragm responsive to an applied bias, signal and/or in response to an externally applied mechanical/acoustic/pneumatic pressure. The metal or composite membrane can have a thickness gradient.

In another embodiment, the disclosure relates to an array of addressable pixels, the array comprising: a substrate defining a plurality of cavities thereon; a membrane covering a portion of the substrate and forming a plurality of diaphragms with the respective plurality of the cavities; a first electrode integrated with a first of the plurality of cavities and forming a first electrode pair with a corresponding first diaphragm; and a second electrode integrated with a second of the plurality of cavities and forming a second electrode pair with a corresponding second diaphragm; wherein the membrane is a composite of a first and a second material, and wherein the first material and the second material have a complementary thickness gradient such that as the thickness of the first and the second material varies across the substrate, the composite thickness remains substantially constant.

### BRIEF DESCRIPTION OF THE DRAWINGS

These and other embodiments of the disclosure will be discussed with reference to the following exemplary and non-limiting illustrations, in which like elements are numbered similarly, and where:

FIGS. 1A-1G schematically illustrate a contact transfer printing process according to one embodiment of the disclosure;

FIG. 2 schematically illustrate a solvent-assisted contact transfer printing process according to one embodiment of the disclosure;

FIG. 3A is an optical microscopy image of a gold diaphragm formed according to an embodiment of the disclosure;

FIG. 3B shows deflection profile of a diaphragm of FIG. 3A under electrostatic pressure;

FIG. 4 is a 2D array of contact-printed metal membranes on flexible substrate according to one implementation of the disclosure;

FIG. 5 is a profile representation of an exemplary apparatus for manipulating light;

FIG. 6 shows a digital mirror according to one embodiment of the disclosure;

FIGS. 7A-7C show tunable optical micro-cavity resonators according to embodiments of the disclosure;

FIG. 8 shows an exemplary array having multiple cavities where each cavity has a varying thickness diaphragm; and

FIG. 9 schematically illustrates a capacitive zipper actuator according to an embodiment of the disclosure.

### DETAILED DESCRIPTION

The disclosed embodiments provide sensitive pixel arrays formed using solvent-assisted or unassisted release processes. Such products can be used in sensitive acoustic and optical devices as well as pressure sensors and various detectors. These products can be fabricated using MEMS fabrication techniques disclosed herein.

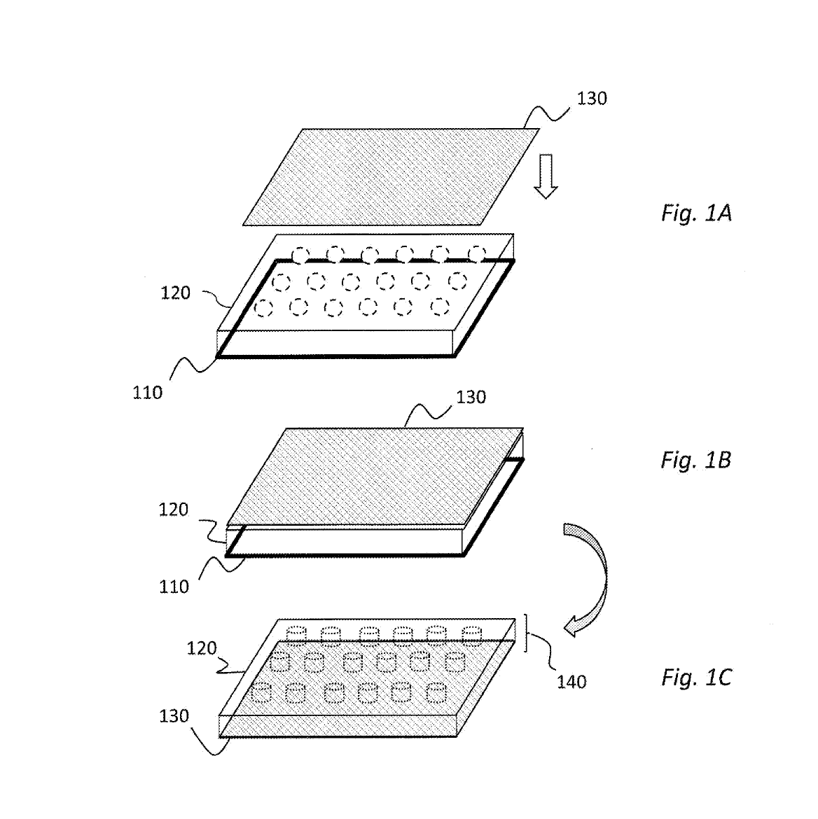

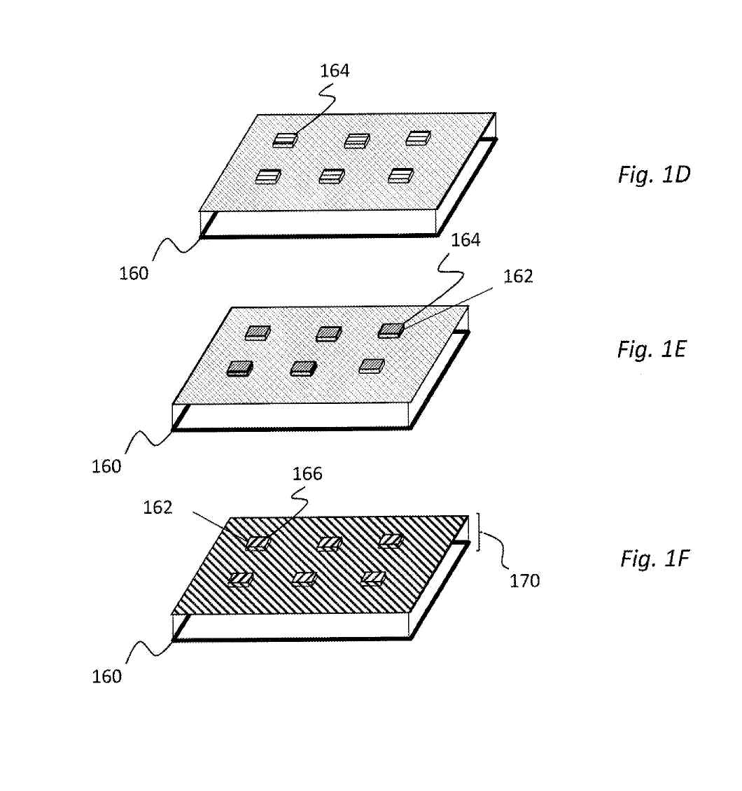

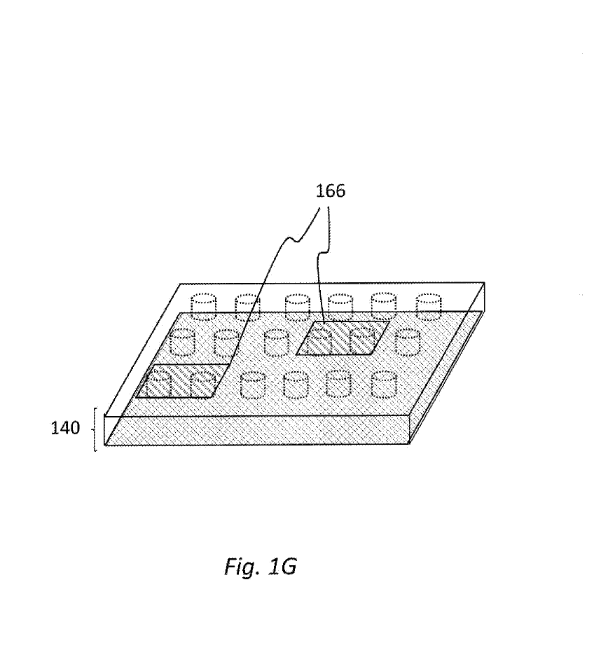

FIGS. 1A-1G schematically illustrate a contact transfer printing process according to one embodiment of the disclosure. The exemplary fabrication process has three general steps: stamp fabrication (FIGS. 1A-1C), transfer pad fabrication (FIGS. 1D-1F) and the transfer process (FIG. 1G). In an exemplary embodiment, the stamp fabrication process starts by spinning uncured poly(dimethylsiloxane) (“PDMS”) 120 onto an epoxy based negative photoresist master mold 110 having cylindrical pillars formed thereon. One such photoresist is SU-8. Next, a glass substrate 130 coated with indium tin oxide (“ITO”) is brought into contact with the PDMS 120 and the combination is cured (FIG. 1B). The master mold 110 is then removed to leave behind stamp 140 (FIG. 1C). The stamp is defined by PDMS layer 120 having cavities therein and supported by ITO glass 130. The cavities can be cylindrical, or may have any other arbitrary desired shape, size or depth. Further the cavities can have one or more sloped walls. Finally, cavities need not be uniform (or symmetrical) and they may have different shapes, sizes and depths in the same substrate. The substrate can be rigid or flexible. An exemplary substrate is ITO-PET (polyethylene terephthalate). In an exemplary embodiment, about 1,000 cylindrical pillars can be formed in an area of 1 mm² with a pitch distance of about 3-7 microns.

The transfer pad fabrication step starts with treating PDMS pad 160 having raised mesas 164 with oxygen plasma (FIG. 1D) and then evaporating an organic release layer 162 over the surface thereof (FIG. 1E). Preferred release layers comprise N,N′-diphenyl-N-N′-bis(3-methylphenyl)-(1,1′-biphenyl)-4,4′-diamine (“TPD”), Alq3 or other organic material having a desired characteristics. Next, a metallic layer 166 is deposited over the organic release layer 162 (FIG. 1F). The metallic layer may be deposited over the entirety of PDMS pad 160, including the raised mesas 164. Other material, including composites can be used in place of metallic layer 164. For example, conductive material, semi-conductive material or a composite material having conductive, semi-conductive or non-conductive material may be deposited over the organic release layer 162. In the embodiment of FIG. 1D-1F, the PDMS transfer pad is designed with raised parallelogram mesa structures 164, which define, with sub-micron resolution, shape of the gold electrodes that will be transferred onto pick-up stamp 140 (FIG. 1C). The gold covered metallic pad having a release layer underneath the gold defines transfer pad 170 (FIG. 1F).

Another method for fabricating the transfer pad starts with evaporating/depositing a thin metallic layer such as aluminum (or some other metal) onto a PDMS pad 160 having raised mesas 164. The PDMS pad with the thin metal layer is then treated with oxygen plasma (FIG. 1D). This is followed by evaporating an organic release layer 162 over the surface of the metal layer covered PDMS pad (FIG. 1E). Preferred release layers comprise N,N′-diphenyl-N-N′-bis(3-methylphenyl)-(1,1′-biphenyl)-4,4′-diamine (“TPD”), Alq3 or other organic material having a desired characteristics. Next, a metallic layer 166 is deposited over the organic release layer 162 (FIG. 1F). The metallic layer may be deposited over the entirety of PDMS pad 160, including the raised mesas 164. Other material, including composites can be used in place of metallic layer 164. For example, conductive material, semi-conductive material or a composite material having conductive, semi-conductive or non-conductive material may be deposited over the organic release layer 162. In the embodiment of FIG. 1D-1F, the PDMS transfer pad is designed with raised parallelogram mesa structures 164 which define, with sub-micron resolution, shape of the gold electrodes that will be transferred onto pick-up stamp 140 (FIG. 1C). The gold covered metallic pad having a release layer underneath the gold defines transfer pad 170 (FIG. 1F).

During the transfer process, pick-up stamp 140 is brought into contact with transfer pad 170. Once contacted, the metallic layer 166 covering raised mesas 164 transfers from pad 170 onto pick-up stamp 140. The result is shown at FIG. 1G. Upon removal of transfer pad 170, metallic layers 166 formed over the mesas adhere to the surfaces of the stamp 140. Because stamp 140 was fabricated with an array of cylindrical cavities, the transferred metallic layer forms a membrane over regions of the substrate. The membrane defines a diaphragm over the cavities of these regions.

In one implementation of gold membrane over a rigid spacer, the pick-up stamp was fabricated by depositing a 400-nm-thick SiO₂ layer using plasma-enhanced chemical vapor deposition on a silicon wafer that forms the back electrode. Photolithographically defined 28-micron-diameter circular cavities are then etched in the SiO₂ layer. The completed stamp was vapor-treated with (3-mercaptopropyl)trimethoxysilane (MPTMS) at 70° C. to enhance adhesion of gold membranes that will be printed on top.

For flexible spacer layers, the pick-up stamp was fabricated by spinning uncured PDMS, mixed in a 10:1 base to curing agent ratio by weight and degassed under vacuum, onto a silanized SU-8 master with cylindrical pillars. The electrically conductive side of an indium tin oxide (“ITO”) coated glass slide/or polymeric substrate slide was then pressed firmly onto the spun PDMS atop the SU-8 master. The resulting structure was then placed in an oven at 60° C. for 4 hours to cure the PDMS between the SU-8 master and the ITO-glass. The pick-up stamp with circular air cavities in the cured PDMS layer was removed from the SU-8 master.

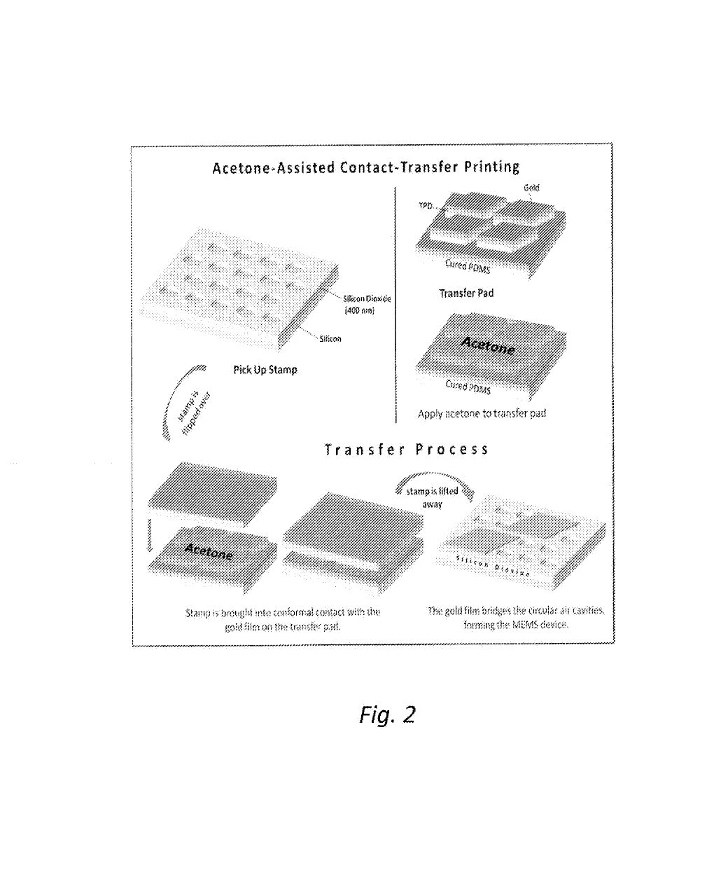

FIG. 2 schematically illustrates a solvent-assisted contact transfer printing process according to one embodiment of the disclosure. The solvent-assisted transfer printing process is disclosed at Applicant's co-pending application Ser. No. 13/604,613, filed Sep. 5, 2012, the recitation of which is incorporated herein in its entirety. The solvent-assisted contact printing process is similar to that shown in FIG. 1, with an additional step of adding a solvent over the metallic layer (e.g., gold) of the to the transfer pad. The added solvent enables dissolving the release layer underneath the metallic layer thereby easing the transfer from the pad to the pick-up stamp. This process is illustrated in the process flow diagram of FIG. 2 where solvent (acetone) is applied to the mesas prior to contacting the transfer pad with the pick-up stamp.

In one implementation gold membrane transfer on a rigid spacer layers was initiated by applying 0.1 ml of acetone to the transfer pad to dissolve the organic release layer (TPD) layer underneath the parallelogram-shaped gold membranes. The pick-up stamp was then placed in contact with gold membranes, which were resting on the mesas but had adhered to the MPTMS treated pick-up stamp. The pickup stamp was then lifted off. The transferred parallelogram-shaped gold membranes covered the cavities in the stamp thereby forming the top electrode of the MEMS device.

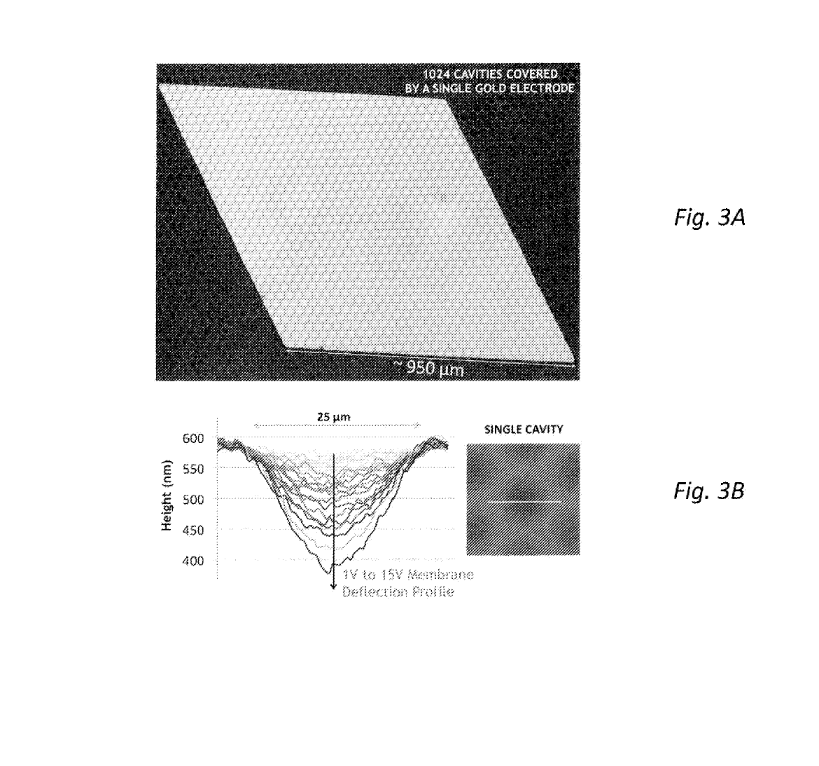

FIG. 3A is an optical microscopy image of a gold diaphragm formed according to an embodiment of the disclosure. Specifically, FIG. 3A shows a microscope image of nearly 1 mm² contact-printed gold electrodes covering about 1024 circular cavities prepared according the disclosed embodiments. Each circular cavity is about 25 μm in diameter. The contact-printed gold electrode was about 150 nm thick and acted as independent diaphragms over each of the respective cavities. FIG. 3B shows deflection profile of a diaphragm of FIG. 3A under electrostatic pressure. Specifically, FIG. 3B shows deflection of the gold electrode over a single 25 μm diameter cavity upon application of about 1V to 15V bias. FIG. 3B also shows the line-cut through the imaged gold membrane above the cavity. Deflections over 150 nm were recorded corresponding to 15 V applied bias.

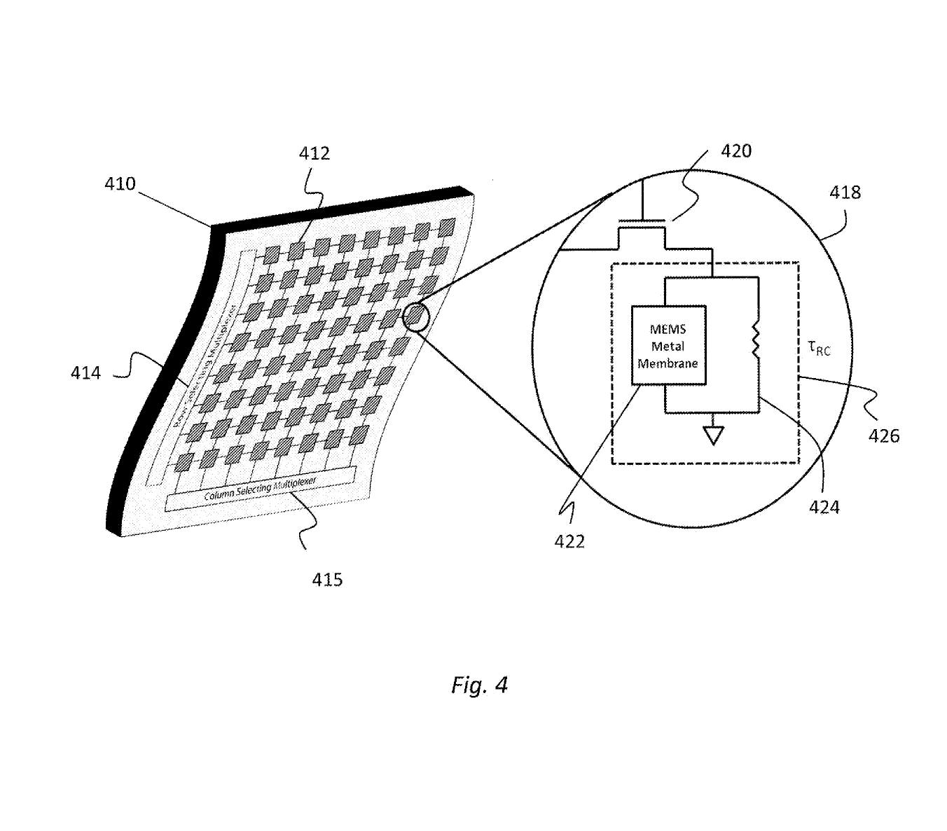

FIG. 4 is a 2D array of contact-printed metal membranes on flexible substrate according to one implementation of the disclosure. Referring to FIG. 4, flexible substrate 410 has an array of metal membranes 412. The array can be formed using the printing methods disclosed herein. The array is arranged in rows and columns and each pixel (membrane) in the array is accessible using row selecting multiplexer 414 and column selecting multiplexer 415. Circuit 418 shows components of an exemplary membrane 412. Transistor 420 biases circuit 424 which comprises a resistor in parallel with the MEMS metal membrane 422 (i.e., metal membrane 412). The metal membrane can comprise one or more layers forming a composite material or it can be a single layer. Further, the membrane can have a uniform thickness or may have a thickness gradient across each pixel. MEMS Metal membrane 422 and its corresponding electrode behave as a capacitor and circuit 424 defines a circuit with time constant, τ_{RC}, and a corresponding frequency response function. The circuit can be configured to respond to desired external forces such as acoustic/pneumatic/mechanical/gas pressure, energy and radio or optical frequency signals- or signals of other frequencies. Alternatively, the circuit can create physical deformation on the surface of the metal membranes 412 to create a tunable electronic device. It should be noted that each pixel 412 can define one diaphragm over a cavity or it may be a single membrane covering a plurality of cavities as shown in FIG. 3A. These embodiments are not limited to flexible substrates and are equally applicable to rigid substrates such as Si-based substrates.

A controller (not shown) can be included to control circuit 418. The controller may comprise a processor circuit in communication with a memory circuit. The memory circuit includes instructions for the processor circuit to supply power to one or more metal membranes 412. For example, a group of metal membranes can be simultaneously or sequentially activated. Alternatively individual membranes can be activated depending on their location or other desired outcome.

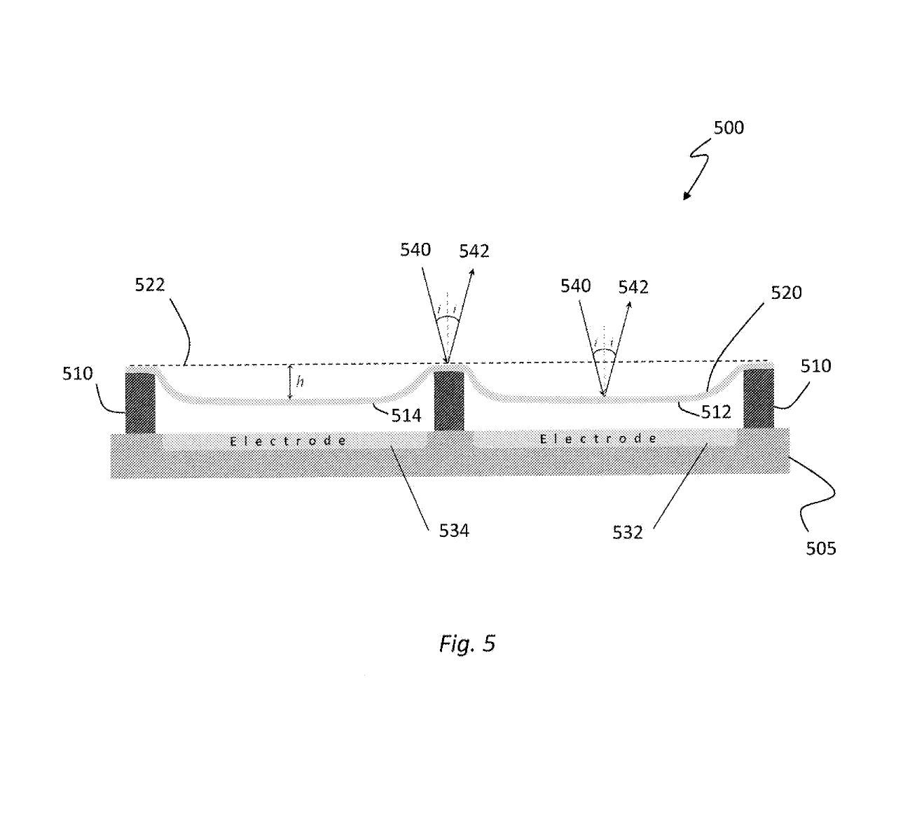

FIG. 5 is a profile representation of an exemplary apparatus for manipulating light. In apparatus 500 of FIG. 5, cavities are created by placing posts (or rigid structures) 510 to support membrane 520. Membrane 520 is stretched over posts 510 using the processes disclosed herein to form diaphragms 512 and 514 between posts 510.

Membrane 520 can be a metallic membrane or a composite of conductive, semi-conductive or non-conductive materials. Further, membrane 520 may have a uniform thickness or it may have a thickness gradient across its surface. Substrate 500 supports electrodes 534 and 532. A power supply (not shown) is coupled to electrodes 532 and 534 as well as membrane 520. As in the embodiment of FIG. 4, a controller (not shown) can direct biasing of diaphragms 512 and 514 such that the diaphragms deflect independently or in unison. Further, the electrodes can be biased differently such that electrode 532 may receive a fraction of the voltage received by electrode 534.

Depending on the biasing state, membrane 520 can have an unbiased state (shown in dashed lines 522) or a biased state (shown with diaphragms 512 and 514. The light incident on membrane 520 is reflected in both biased and unbiased states as shown by arrows 540 and 542. Once biased—and as diaphragm 512 and 514 contort—the reflection characteristics of membrane 520 changes. Given the reflection characteristics of membrane 520, a controller can readily determine the bias voltage that results in the desired reflection. Other factors which can influence the apparatus' deflection include the thickness of the diaphragm (including thickness gradient), positioning of electrodes 532, 534 with respect to diaphragms 512, 514, respectively, and the diaphragm deflection depth, h. When deflection h is large enough, a significant portion of the reflected light intensity decreases due to interference, thus making the membrane covered surface appear rough. Apparatus 500 is able to achieve deflections that are large enough to produce the aforementioned effect for a wide spectrum of visible light and for angles of incident light up to and beyond 60°. The incident angle can vary broadly.

In an exemplary embodiment, the light tuning apparatus 500 can be constructed using a membrane. A substrate having cavities separated by posts or ridges can support the membrane. The constructed diaphragms exhibited both specular and diffused reflection. In the unbiased (and undeflected) state, the device surface can be smooth, reflecting incident light directionally thereby making the surface appear glossy due to specular reflection. When biased, the electrostatic attraction between the membrane and the bottom electrode can cause the electrode to deflect towards the bottom electrode. The greater the bias, the greater the deflection. As the membrane deflects, the overall roughness of the device increases as the metallic surface becomes uneven due the deflected membranes over the cavities and the undeflected membranes over the support structures. The rough surface can result in light being reflected in varying directions and the surface may appear matte due to the diffused reflection. When the surface is made rough, the path difference between the light reflected from the top of the support structure and the top of the deflected membrane (covering the cavity) can result in light interference at the observer.

When the path difference is large, the specularly reflected light intensity is low due to significant interference, hence, producing an effect similar to a rough surface that scatters incident light in various directions. As shown in FIG. 5, h is the minimum uniform deflection of the membrane necessary for the printed metal surface to meet the Rayleigh criterion for rough surface conditions (reduced specular reflection). TABLE 1 shows the minimum membrane deflections necessary (for incident light of different wavelengths) to meet the Rayleigh criterion at various incidence angles for an exemplary embodiment. Deflections greater than those specified in TABLE 1 will result in a diffused reflection. SiO₂-spacer-layer devices are capable of achieving these deflections at 15 volts or less. Exemplary devices can function as reconfigurable-reflectivity surfaces for angles of incidence up to 67° for approximately 550 nm wavelength incident light. The range of incidence angles can be further increased by increasing the thickness of the dielectric spacer layer.

TABLE 1
Exemplary Minimum Deflection of Metal Membranes

| | MINIMUM DEFLECTION NEEDED TO | | |
|---|---|---|---|
| | ACHIEVE RAYLEIGH ROUGHNESS (H) | | |
| ANGLE OF | 680 nm | 550 nm | 420 nm |
| INCI- | WAVELENGTH | WAVELENGTH | WAVELENGTH |
| DENCE (I) | (RED) | (GREEN) | (BLUE) |
| 30° | 98 nm | 79 nm | 61 nm |
| 45° | 120 nm | 97 nm | 74 nm |
| 60° | 170 nm | 137 nm | 105 nm |
| 85° | 975 nm | 789 nm | 602 nm |

The surface roughness can be increased by patterning the underlying spacer/dielectric layer with cavities of different shapes and areas, resulting in sharper deflection profiles for membranes over non-circular cavities. The ability to print these thin metal membranes on both flexible and rigid substrates enables the demonstration of sensor skins with analog, electronically-controllable reflectivity. Additionally, by patterning the underlying electrodes, different regions of the metal membranes can be deflected by different amounts, hence enabling the skin to exhibit spatially-varying reflectivity that can be reconfigured in real time by appropriate application specific integrated circuits.

An exemplary application for the tunable apparatus 500 (FIG. 5) is textured electronic displays. The membranes can be coated on an electronic display and controlled to spatially vary the reflectivity of the display such that the different textures of the objects in the image being displayed can be optically emulated and conveyed by directing/manipulating the reflection of light.

In another exemplary embodiment, apparatus 500 can be used as a detector. In this embodiment, a meter can be connected to diaphragm 520 and one or both of electrodes 532 and 534. The meter (not shown) communicates with one or more of the electrode pairs and detects capacitance change between the electrode and its diaphragm when an external signal impacts the membrane.

A controller (not shown), having a processor circuit and a memory circuit, can be configured with the meter such that the controller receives a signal from the meter and identifies a change in capacitance corresponding to the received signal. More specifically, the change is determined in response to the extent of deflection (h) in the diaphragm(s) caused by the external resource. The electrode pair communicates change in potential to the meter as the diaphragm of the electrode pair deflects. Alternatively, it may detect a change in current when the diaphragm is deflecting.

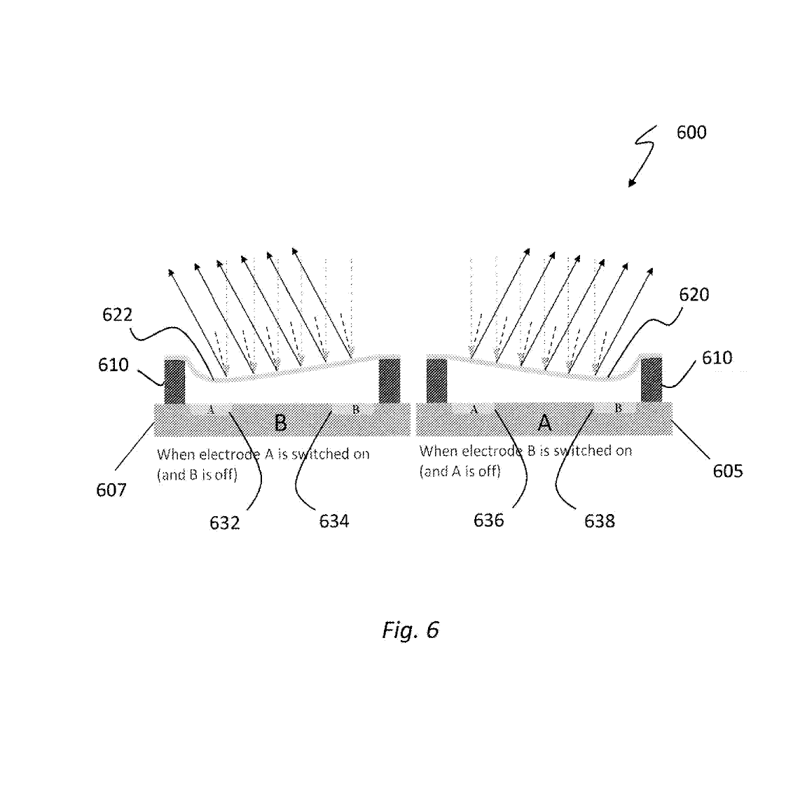

FIG. 6 shows a digital mirror according to one embodiment of the disclosure. The exemplary digital mirror 600 of FIG. 6 is shown with two pixels, though it may have one pixel or an array of pixels implementing the disclosed principles. Referring to FIG. 6, each pixel is shown to have a substrate, a diaphragm and a plurality of independently addressable electrodes. Specifically, pixel A has diaphragm 620 supported by posts 610 and substrate 605. Electrodes 636 and 638 are formed over or integrated with substrate 605 and can be independently biased using a controller (not shown). Pixel B includes substrate 607 having addressable electrodes 632 and 634 as well as posts 610 supporting diaphragm 622. Posts 610 can be formed over the substrate or they can define ridges of a cavity formed according to the processes disclosed herein. The substrate 605 and 607 may define a single substrate. That is, either substrates 605 or 607 can support a single membrane over a plurality of cavities separated by posts 610 such that each diaphragm covering a cavity can deflect in a different direction.

Directional minor 600 can asymmetrically deflect diaphragms 620 and 622 when the corresponding electrodes are addressed asymmetrically. In a broader application, a surface covered with multiple diaphragms can act as a directional mirror by patterning the electrodes underneath the diaphragm (e.g., gold membrane). The diaphragm can be made to deflect asymmetrically by switching on only one of the two electrodes underneath the membrane, or by applying different voltages to the two electrodes. While only two electrodes are shown for each of pixels A and B, the disclosed principles can be applied to having multiple electrodes associated with each pixel.

The asymmetrical deflection of the diaphragms causes the reflecting surface to shift, hence changing the direction in which the incident light is reflected. Digital minor 600 has at least three electronically-controlled digital states capable of specularly reflecting light in at least three different directions. The number of digital directions that such a mirror has can be increased by increasing the number of electrodes. Reflective surfaces made according to the embodiment of FIG. 6 have potential applications in military, camouflage, building and vehicular window-coatings, digital light projection/processing, digital micromirror devices, and in adaptive optics to achieve wavefront control and correction of optical aberrations, etc.

The angle of asymmetrical deflection can be controlled in analog mode by varying the voltage applied to any one of the electrodes. The asymmetrical deflection causes the normal of the reflecting surface to rotate, hence, changing the direction in which the incident light is reflected. The degree of asymmetrical deflection can be increased or decreased by increasing or decreasing the voltage applied to the ON electrode. When both electrodes are switched on or switched off, most of the incident light is reflected back in the incident direction. The ability of a surface to direct specularly-reflected light and to control the reflectivity (diffused vs. specular) can be achieved on a single skin, as illustrated in TABLE 2.

TABLE 2
Device functionality for digital mirror 600

| Electrode State | | |
|---|---|---|
| Electrode A | Electrode B | Device Functionality |
| On | Off | Directed Specular Reflection |
| | | (direction 1) |
| Off | On | Directed Specular Reflection |
| | | (direction 2) |
| On (low voltage) | On (low voltage) | Directed Specular Reflection |
| | | (direction 3) |
| On (high voltage) | On (high voltage) | Diffused Reflection |
| Off | Off | Directed Specular Reflection |
| | | (direction 3) |

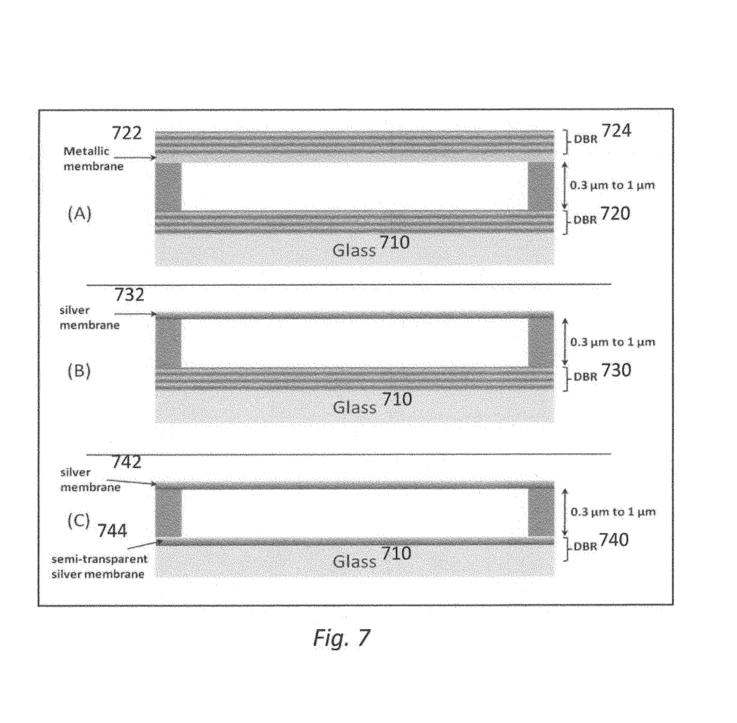

FIGS. 7A-C show tunable optical micro-cavity resonators according to embodiments of the disclosure. Metal membranes printed atop of cavities can function as tunable optical micro-cavity resonators. The micro-cavity resonators can be implemented in various ways by using different combinations of distributed Bragg reflectors (DBRs) and metallic mirrors. FIGS. 7A-7C show exemplary implementations of different micro-cavity resonators.

The quality factor (Q-factor) of these resonators can vary from 20 to 57000, depending on the combination used, and the input light frequency. The Q-factor also depends on the spacing between the two reflecting surfaces that comprise an optical micro-cavity. Since one of the minors in the micro-cavity can be deflected by applying an electrical signal, the wavelength of light inside the cavity can be changed thereby changing the optical resonance mode of the cavity. By changing the optical resonance mode of the cavity, the wavelength at which the cavity lases can be controlled. The printed membrane technology enables the additive fabrication of tunable lasers. Moreover, since multiple devices can be printed on a single substrate, and addressed and/or controlled independently, it is possible to demonstrate multiple lasing sources of different frequencies on a single substrate. Such devices have a myriad of applications such as optical switches for communications.

FIG. 7A shows a first exemplary tunable optical micro-cavity resonator using contact-transfer printing. In FIG. 7A, glass substrate 710 supports bottom DBR layer 720 and a plurality of posts, which in combination with metallic membrane 722, form a cavity of about 0.3-1 μm depth. The top DBR layer 724 is formed over metallic membrane 722. A tunable optical micro-cavity constructed according to these specifications provides a DBR/DBR micro-cavity where top DBR layer 724 can deflect due the metallic membrane underneath to provide a Q factor of about 57000.

FIG. 7B shows a second exemplary tunable optical micro-cavity resonator using contact transfer printing. In FIG. 7B, glass substrate 710 supports bottom DBR layer 730, a plurality of posts and silver membrane 732 to form a cavity of about 0.3-1 μm depth. A tunable optical micro-cavity constructed according to these specifications results in a DBR/metal micro-cavity with a deflectable silver mirror with a Q factor of about 142.

FIG. 7C shows a third exemplary tunable optical micro-cavity resonator using contact transfer printing. In FIG. 7C, glass substrate 710 supports semi-transparent silver membrane 744, a plurality of posts and silver membrane 742 to form a cavity of about 0.3-1 μm depth. The combination of semi-transparent silver membrane 744 and a portion of glass substrate 710 define bottom DBR layer 740. A tunable optical micro-cavity constructed according to these specifications results in a metal/metal micro-cavity with a deflectable silver mirror with a Q factor of about 20. All Q-factor values were specified for input light of 545 THz frequency with a distance of 500-nm between the two minors.

The flexural rigidity of a deflectable diaphragm/membrane depends directly on the cube of its thickness, (i.e., t³). The thicker the membrane, the more rigid it will behave and it will exhibit a smaller deflection in response to applied bias or force. Acoustic devices fabricated using conventional integrated circuit fabrication technologies have a deflecting diaphragm over a single resonant cavity structure. The thickness of the diaphragm is uniform over the cavity. This limits the functionality of the device both in terms of the device's frequency response, and its ability to function as a reversible transducer without performance compromise.

The technology disclosed herein enables fabrication of acoustic devices with multiple cavities covered by a membrane. The membrane can be contact-printed over the cavities. In one embodiment of the disclosure, the membrane may have non-uniform cross-sectional thickness. For example, the membrane thickness can vary continuously across the membrane length, resulting in multiple cavities being bridged by a single membrane of varying thickness. In this manner, each cavity or a group of cavities of an array can be covered by a certain thickness (or range of thicknesses) of the same conducting membrane.

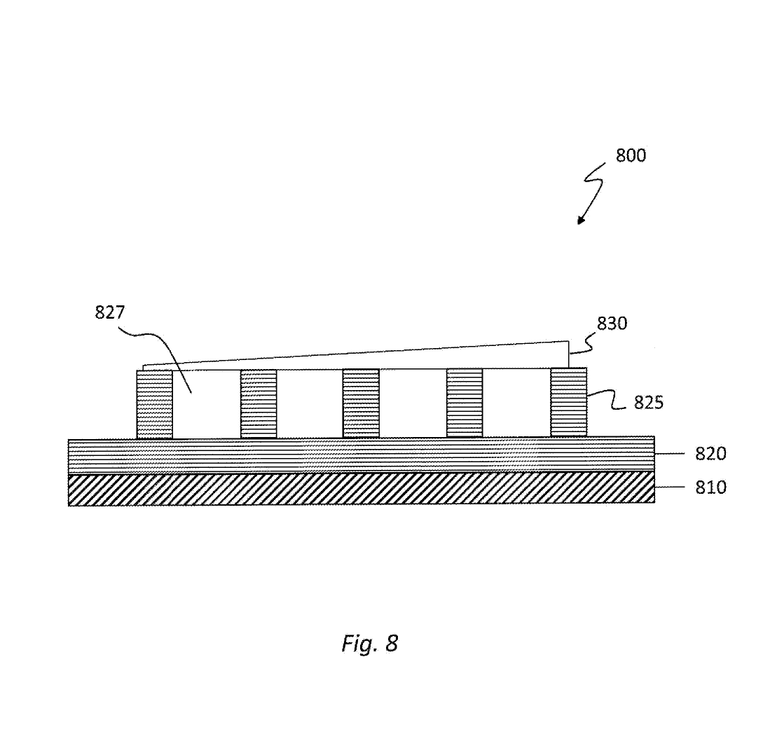

FIG. 8 shows an exemplary array having multiple cavities where each cavity has a varying thickness diaphragm and where all the diaphragms are part of a single deflectable membrane of varying thickness. Substrate 810 is a silicon substrate supporting dielectric spacer layer (e.g., SiO₂) 820 and posts 825. Membrane 830 is formed over posts 825 to create a plurality of cavities 827 with the respective plurality of diaphragms bounding the cavities. The thickness of membrane 830 varies across the length of substrate 810 such that multiple cavities are covered by a single film of varying thickness. Thus, each cavity supports a diaphragm of varying thickness and the diaphragms may have different average thicknesses from each other. Membrane 830 can be a gold, metal or semiconductor (doped or undoped) film. Membrane 830 can also be an insulator-backed composite film of the aforementioned materials. The covered cavities can be commonly actuated or each cavity can be addressed individually. While not shown, each cavity has one or more electrodes to engage its respective diaphragm.

The membrane of varying thickness can be replaced with a graded film-composite such that the suspended, deflectable diaphragm/membrane includes layers of different materials, and the thickness of the entire composite membrane varies continuously across the membrane length. A graded film of doped or undoped semiconductor materials such as silicon, silicon nitride, polysilicon, or other materials, and compositions thereof can also be used to implement the deflecting membrane. The maximum deflection of the membrane over a group of cavities can be controlled by varying the diameter or the size of the cavities covered by a single membrane and by varying the applied bias.

The membrane of varying thickness can have a continuous thickness gradient. Alternatively, the gradient can be discrete thereby giving the membrane a stepped thickness profile. The gradient may also vary in both a Cartesian geometry and/or in a cylindrical/ polar geometry. That is, the membrane of any arbitrary shape (circular, square, parallelogram, any shape) can be thickest in the center and then thin out away from the center. This provides a shape that is thinnest at the edge of the membrane and thicker at the center. The membrane can also be thickest at the edges and thinnest at the center, or any combination thereof. The gradient may also have a wedge-shaped form such that it is thick at one end and thin at the other end.

Finally, the membrane can have an arbitrarily varying thickness profile.

The cavities themselves can have varying sizes and shapes. For example, cavities covered by a single membrane or plurality of membranes on a single substrate can have different diameters and/or different shapes, depth or size. The cavities may be covered by a varying thickness membrane or a uniform-thickness membrane.

The varying thickness diaphragm improves device functionality in several ways. First, the varying thickness diaphragm enables reversible transduction using the same printed device. Thus, a single printed device can be used as a sensor (microphone for sound detection) or as an actuator (micro-speakerphone for sound production), without significant performance decrease in either mode. Second, the disclosed embodiments enable the printing of microphone and speakerphone as two separate devices on a single substrate in a single printing step. The substrate can be a rigid substrate (such as silicon, silicon dioxide, or other rigid substrates), a flexible polymeric or viscoelastic substrate (e.g., PDMS), or two rigid substrates coupled by a flexible substrate. Third, it enables a single device to potentially be used for both human audio range applications and for ultrasound applications, in both sensor and actuator modes.

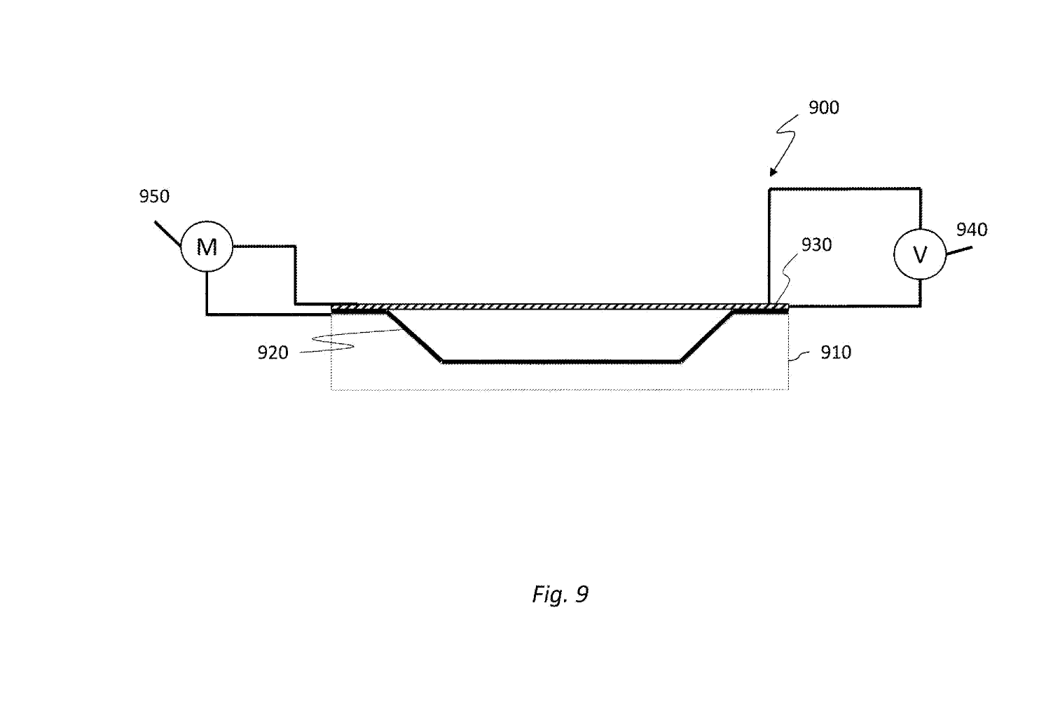

FIG. 9 schematically illustrates a capacitive zipper actuator according to an embodiment of the disclosure. The capacitive actuator can be used for larger membrane deflection at smaller applied bias. The capacitive zipper actuator of FIG. 9 comprises conductor substrate 910, insulator layer 920 and conductive membrane 930, meter 950 and power supply 940. The insulator layer 920 can cover all or a portion of the cavity. The insulator layer 920 may also cover all or portions of the one or more electrodes corresponding to a diaphragm. The conductive membrane may comprise one or multiple layers where at least one layer is conductive. Substrate 910 is coated with an insulating material to form insulator 920. The conductive membrane is then transferred over the insulator 920 using the contact-transfer techniques disclosed herein. Actuator 900 can produce larger recoverable deflections of the suspended membrane responsive to a smaller bias. The zipper actuator is particularly suitable for applications in acoustics and optics.

Other applications of the disclosed principles include sound detection and direction detection. Sound detection can be implemented using the disclosed embodiments as acoustic sensors or microphones. The movement of diaphragms in response to externally-applied acoustic pressure will cause deflection in the diaphragm. The deflection can be measured to determine the magnitude of the applied acoustic pressure. The direction of the sound waves can also be measured by using groups of cavities or individual cavities or arrays of cavities (all covered by a single membrane or a plurality of membranes) as individual microphones (detectors) to detect the delay between the incoming acoustic pressure wavefronts for both human audio range and ultrasound applications. In this manner, the time delay from one group of affected diaphragms to another group can indicate the direction of the wavefront. In still another embodiment, groups of cavities or individual cavities or arrays of cavities (all covered by a single membrane or a plurality of membranes) can be used to implement beam forming for acoustic applications to thereby direct sound waves and ultrasound waves using phased arrays of the printed membrane devices functioning as micro-speakers.

While the principles of the disclosure have been illustrated in relation to the exemplary embodiments shown herein, the principles of the disclosure are not limited thereto and include any modification, variation or permutation thereof.

What is claimed is:

1. A tunable optical device, comprising:
a substrate defining an array of cavities with each cavity supporting an electrode;
a reflective membrane formed over the substrate so as to form a plurality of diaphragms, each diaphragm corresponding to a respective one of the plurality of cavities and each diaphragm and corresponding electrode defining an electrode pair;
power source for biasing a first electrode pair and a second electrode pair;
wherein each of the first electrode pair and the second electrode pair deflects responsive to an applied bias thereby distorting reflection of an incident light.

2. The device of claim 1, wherein the substrate is a rigid or a flexible substrate.

3. The device of claim 1, wherein the reflective membrane is a metallic membrane selected from the group consisting of gold, silver, aluminum, chrome, copper, or combinations thereof.

4. The device of claim 1, wherein the first electrode pair and the second electrode pair deflect in substantially the same direction.

5. The device of claim 1, wherein the first electrode pair and the second electrode pair deflect in different directions.

6. The device of claim 1, wherein the power source biases the first electrode pair independently of the second electrode pair.

7. The device of claim 1, wherein the power source biases the first electrode pair and the second electrode pair substantially simultaneously.

8. The device of claim 1, wherein the power source biases the first electrode pair and the second electrode pair sequentially.

9. The device of claim 1, wherein the reflective membrane is a composite of different materials.

10. The device of claim 1, further comprising an insulator layer covering a portion of at least one cavity.

11. The array of claim 1, wherein at least one of the cavities has sloping sidewalls.

12. A tunable optical micromirror device, comprising:
a diaphragm formed over a cavity and supported by a structure;
a first electrode and a second electrode positioned in the cavity;
a power supply for biasing each of the first electrode, the second electrode and the diaphragm; and
a controller for controlling the power supply to bias one or more of the first electrode, the second electrode and the diaphragm;
wherein the controller activates the first electrode or the second electrode, and wherein activating one of the first electrode or the second electrode deflects a region of the diaphragm.

13. The device of claim 12, wherein the diaphragm is a composite of metallic, semiconductor and non-conductive material.

14. The device of claim 12, wherein at least one of the first or the second electrode is integrated into the cavity.

15. The device of claim 12, wherein activating the first electrode deflects the diaphragm in a first direction and activating the second electrode deflects the diaphragm in a second direction.

16. The device of claim 12, wherein activating the first electrode or the second electrode deflects the diaphragm in a first direction.

17. The device of claim 12, wherein the controller activates the first and the second electrodes simultaneously or sequentially.

18. The device of claim 12, wherein the controller activates the first electrode or the second electrode independently of each other.

19. The device of claim 12, wherein the diaphragm has a thickness gradient.

20. The device of claim 12, further comprising an insulator layer covering a portion of the cavity.

21. The device of claim 12, wherein the first and the second electrode are positioned at or below the cavity.

22. The device of claim 12, wherein the plurality of cavities have one or more of different shapes, sizes or depths.

23. The device of claim 12, wherein the cavity has sloping sidewalls.
